(19) United States
(12) Patent Application Publication
(10) Pub. No.: US 2024/0387557 A1
(43) Pub. Date: Nov. 21, 2024

(54) DISPLAY DEVICE

(71) Applicant: Innolux Corporation, Miaoli County (TW)

(72) Inventor: Chun-Hsien Lin, Miaoli County (TW)

(73) Assignee: Innolux Corporation, Miaoli County (TW)

(21) Appl. No.: 18/632,303

(22) Filed: Apr. 11, 2024

(30) Foreign Application Priority Data
May 17, 2023 (CN) 202310557694.8

(51) Int. Cl. H01L 27/12; G09G 3/32

(52) U.S. Cl. CPC H01L 27/1222; G09G 3/32; H01L 27/1225; G09G 2300/0426; G09G 2300/0842; G09G 2320/0242

(57) ABSTRACT

A display device including a green sub-pixel, a red sub-pixel, and a blue sub-pixel is provided. The green sub-pixel includes a first driving transistor having a first channel width to length ratio being W₁/L₁. The red sub-pixel includes a second driving transistor having a second channel width to length ratio being W₂/L₂. The blue sub-pixel includes a third driving transistor having a third channel width to length ratio being W₃/L₃. W₁/L₁>W₃/L₃, and W₂/L₂>W₃/L₃.

### CROSS-REFERENCE TO RELATED APPLICATION

This application claims the priority benefit of China application serial no. 202310557694.8 filed on May 17, 2023. The entirety of the above-mentioned patent application is hereby incorporated by reference herein and made a part of this specification.

### BACKGROUND

### Technical Field

The disclosure relates to a display device.

### Description of Related Art

Light-emitting diodes have the characteristics of high color saturation and power saving, and have become one of the important development projects in the field of display devices.

### SUMMARY

A display device, which has flexible driving operation, is provided in the disclosure.

A display device of the disclosure includes a green sub-pixel, a red sub-pixel, and a blue sub-pixel. The green sub-pixel includes a first driving transistor having a first channel width to length ratio being W₁/L₁. The red sub-pixel includes a second driving transistor having a second channel width to length ratio being W₂/L₂. The blue sub-pixel includes a third driving transistor having a third channel width to length ratio being W₃/L₃. W₁/L₁>W₃/L₃, and W₂/L₂>W₃/L₃.

To sum up, the display device of the disclosed embodiment is more flexible in controlling the driving of sub-pixels of different colors.

### BRIEF DESCRIPTION OF THE DRAWINGS

FIG. 1 is a schematic diagram of a display device according to an embodiment of the disclosure.

FIG. 2 is a schematic diagram of a display device according to an embodiment of the disclosure.

FIG. 3 is a schematic diagram of a display device according to an embodiment of the disclosure.

FIG. 4 is a schematic diagram of a display device according to an embodiment of the disclosure.

FIG. 5 is a schematic diagram of a driving transistor of a display device according to an embodiment of the disclosure.

### DETAILED DESCRIPTION OF DISCLOSED EMBODIMENTS

References of the exemplary embodiments of the disclosure are to be made in detail. Examples of the exemplary embodiments are illustrated in the drawings. If applicable, the same reference numerals in the drawings and the descriptions indicate the same or similar parts.

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended claims to refer to specific elements. It should be understood by those skilled in the art that electronic apparatus manufacturers may refer to the same elements by different names. The disclosure does not intend to distinguish between elements that have the same function but have different names. In the following description and claims, words such as “comprising”, “including”, and “having” are open-ended words, so they should be interpreted as meaning “including but not limited to . . . ”. Accordingly, when the terms “comprising”, “including”, and/or “having” are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being “disposed or formed on” another component, it may be directly disposed or formed on the other component or other components may be present therebetween. On the other hand, when a component is referred to as being “directly disposed or formed on” another member, there are no components in between. Additionally, when a component is referred to as being “disposed or formed on” another component, the two are in a top-down relationship when viewed from above, and the component may be above or below the other component, depending on the orientation of the device.

It should be understood that when a component or film layer is referred to as being “connected to” another component or film layer, it may be directly connected to another component or film layer, or intervening components or film layers may be present therebetween. When a component is referred to as being “directly connected to” another component or film layer, there are no intervening components or film layers therebetween. In addition, when a component is referred to as being “coupled to another component (or a variation thereof)”, it may be directly connected to this other component, and indirectly (e.g., electrically connected) to this other component through one or more components.

The terms “about”, “equal to”, “equal” or “same”, “substantially” or “generally” are interpreted as within 20% of a given value or range, or interpreted as within 10%, 5%, 3%, 2%, 1%, or 0.5% of the given value or range.

The terms such as “first”, “second”, etc. used in the description and the claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the claims and the description, and accordingly, the first component in the description may be the second component in the claims.

In the disclosure, an electronic device may include a display device, a backlight device, an antenna device, a sensing device or a splicing device, but is not limited thereto. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light, heat or ultrasonic waves, but not limited thereto. Electronic elements may include passive and active elements, such as capacitors, resistors, inductors, diodes, transistors, or semiconductor chips, etc. The diode may include a light-emitting diode or a photodiode. The light-emitting diode may include, for example, an organic light-emitting diode (OLED), a mini light-emitting diode (mini LED), a micro light-emitting diode (micro LED), or a quantum dot light-emitting diode (quantum dot LED), but not limited thereto. The splicing device may be, for example, a display splicing device or an antenna splicing device, but not limited thereto. It should be noted that, the electronic device may be any arrangement and combination of the foregoing, but not limited thereto. Hereinafter, the display device is used as the electronic device or the splicing device to illustrate the disclosure, but the disclosure is not limited thereto.

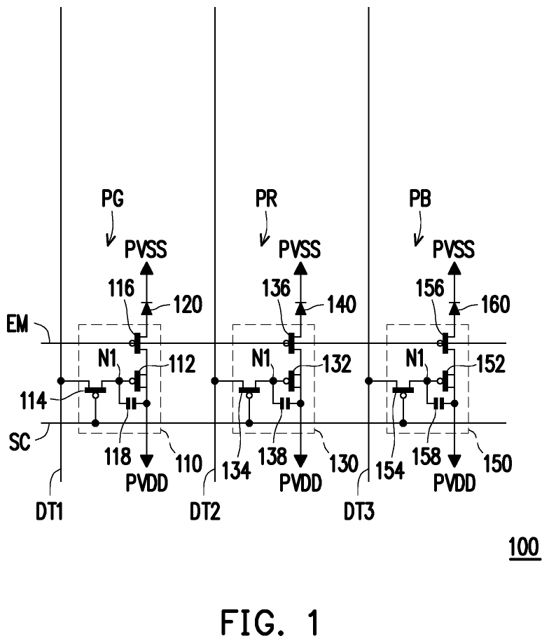

FIG. 1 is a schematic diagram of a display device according to an embodiment of the disclosure A display device 100 includes a green sub-pixel PG, a red sub-pixel PR, and a blue sub-pixel PB. The green sub-pixel PG is suitable for emitting green light, the red sub-pixel PR is suitable for emitting red light, and the blue sub-pixel PB is suitable for emitting blue light. The green sub-pixel PG, the red sub-pixel PR, and the blue sub-pixel PB are arranged side by side so as not to block the light emitted from each other. The green sub-pixel PG may include a first driving transistor 112, the red sub-pixel PR may include a second driving transistor 132, and the blue sub-pixel PB may include a third driving transistor 152. The first driving transistor 112, the second driving transistor 132, and the third driving transistor 152 may have different channel designs. For example, the first channel width to length ratio of the first driving transistor 112 is W₁/L₁; the second channel width to length ratio of the second driving transistor 132 is W₂/L₂; the third channel width to length ratio of the third driving transistor 152 is W₃/L₃, in which W₁/L₁>W₃/L₃, and W₂/L₂>W₃/L₃.

Specifically, the green sub-pixel PG includes a pixel driving circuit 110 and a light-emitting element 120, and the light-emitting element 120 is electrically connected to the pixel driving circuit 110. The light-emitting element 120 of the green sub-pixel PG may include a green light-emitting diode. The pixel driving circuit 110 is configured to drive the green light-emitting diode in the light-emitting element 120 to emit green light. The pixel driving circuit 110 may include a first driving transistor 112, a first scanning transistor 114, a first switching transistor 116, and a first storage capacitor 118. In this embodiment, the first terminal of the first driving transistor 112 is coupled to the operating voltage PVDD. The second terminal of the first driving transistor 112 is coupled to the first terminal of the first switching transistor 116. The first terminal of the first storage capacitor 118 is coupled to the first terminal of the first driving transistor 112, and the second terminal of the first storage capacitor 118 is coupled to the control terminal of the first driving transistor 112. The control terminal of the first driving transistor 112 is coupled to the first scanning transistor 114 through the circuit node N1. The first terminal of the first scanning transistor 114 may be coupled to the first data line DT1. The control terminal of the first scanning transistor 114 may be coupled to the scan line SC. The second terminal of the first scanning transistor 114 is coupled to the control terminal of the first driving transistor 112 through the circuit node N1. The second terminal of the first switching transistor 116 is coupled to the first terminal of the light-emitting element 120. The second terminal of the light-emitting element 120 is coupled to the ground voltage PVSS. In addition, the control terminal of the first switching transistor 116 may be coupled to the control line EM. The first data line DT1 is configured to provide data signals, the scan line SC is configured to provide scan signals, and the control line EM is configured to provide control signals. Therefore, the first terminal of the first scanning transistor 114 may receive the data signal, the control terminal of the first scanning transistor 114 may receive the scan signal, and the control terminal of the first switching transistor 116 may receive the control signal.

The design of the red sub-pixel PR is similar to that of the green sub-pixel PG. Specifically, the red sub-pixel PR includes a pixel driving circuit 130 and a light-emitting element 140. The light-emitting element 140 of the red sub-pixel PR may include a red light-emitting diode. The pixel driving circuit 130 is configured to drive the red light-emitting diode in the light-emitting element 140 to emit red light. The pixel driving circuit 130 may include a second driving transistor 132, a second scanning transistor 134, a second switching transistor 136, and a second storage capacitor 138. In this embodiment, the first terminal of the second driving transistor 132 is coupled to the operating voltage PVDD. The second terminal of the second driving transistor 132 is coupled to the first terminal of the second switching transistor 136. The first terminal of the second storage capacitor 138 is coupled to the first terminal of the second driving transistor 132, and the second terminal of the second storage capacitor 138 is coupled to the control terminal of the second driving transistor 132. The control terminal of the second driving transistor 132 is coupled to the second scanning transistor 134 through the circuit node N1. The first terminal of the second scanning transistor 134 may be coupled to the second data line DT2. The control terminal of the second scanning transistor 134 may be coupled to the scan line SC. The second terminal of the second scanning transistor 134 is coupled to the control terminal of the second driving transistor 132 through the circuit node N1. The second terminal of the second switching transistor 136 is coupled to the first terminal of the light-emitting element 140. The second terminal of the light-emitting element 140 is coupled to the ground voltage PVSS. In addition, the control terminal of the second switching transistor 136 may be coupled to the control line EM. The second data line DT2 is configured to provide data signals, the scan line SC is configured to provide scan signals, and the control line EM is configured to provide control signals. Therefore, the first terminal of the second scanning transistor 134 may receive the data signal, the control terminal of the second scanning transistor 134 may receive the scan signal, and the control terminal of the second switching transistor 136 may receive the control signal.

The design of the blue sub-pixel PB is also similar to that of the green sub-pixel PG. Specifically, the blue sub-pixel PB includes a pixel driving circuit 150 and a light-emitting element 160. The light-emitting element 160 of the blue sub-pixel PB may include a blue light-emitting diode. The pixel driving circuit 150 is configured to drive the blue light-emitting diode in the light-emitting element 160 to emit blue light. The pixel driving circuit 150 may include a third driving transistor 152, a third scanning transistor 154, a third switching transistor 156, and a third storage capacitor 158. In this embodiment, the first terminal of the third driving transistor 152 is coupled to the operating voltage PVDD. The second terminal of the third driving transistor 152 is coupled to the first terminal of the third switching transistor 156. The first terminal of the third storage capacitor 158 is coupled to the first terminal of the third driving transistor 152, and the second terminal of the third storage capacitor 158 is coupled to the control terminal of the third driving transistor 152. The control terminal of the third driving transistor 152 is coupled to the third scanning transistor 154 through the circuit node N1. The first terminal of the third scanning transistor 154 may be coupled to the third data line DT3. The control terminal of the third scanning transistor 154 may be coupled to the scan line SC. The second terminal of the third scanning transistor 154 is coupled to the control terminal of the third driving transistor 152 through the circuit node N1. The second terminal of the third switching transistor 156 is coupled to the first terminal of the light-emitting element 160. The second terminal of the light-emitting element 160 is coupled to the ground voltage PVSS. In addition, the control terminal of the third switching transistor 156 may be coupled to the control line EM. The third data line DT3 is configured to provide data signals, the scan line SC is configured to provide scan signals, and the control line EM is configured to provide control signals. Therefore, the first terminal of the third scanning transistor 154 may receive the data signal, the control terminal of the third scanning transistor 154 may receive the scan signal, and the control terminal of the third switching transistor 156 may receive the control signal.

The green sub-pixel PG, the red sub-pixel PR, and the blue sub-pixel PB all adopt light-emitting diodes to emit the required chromatic light, and the light-emitting diodes of the green sub-pixel PG, the red sub-pixel PR, and the blue sub-pixel PB may be different. For example, the green sub-pixel PG, the red sub-pixel PR and the blue sub-pixel PB may respectively adopt green light-emitting diodes, red light-emitting diodes, and blue light-emitting diodes. However, light-emitting diodes of different chromatic light have different electrical characteristics. For example, light-emitting diodes of different chromatic light have different forward bias voltages and require different operating current densities. Therefore, if the green sub-pixel PG, the red sub-pixel PR and the blue sub-pixel PB are driven by the same driving circuit, it may not be easy to achieve the desired display effect.

In addition, generally speaking, the human eye has different sensitivities to different chromatic light. Therefore, when displaying a white light image, the green sub-pixel PG, the red sub-pixel PR, and the blue sub-pixel PB must provide different luminance to present a white light image that satisfies human perception. For example, when presenting predetermined white light, the luminance of the green sub-pixel PG is greater than the luminance of the red sub-pixel PR, and the luminance of the red sub-pixel PR is greater than the luminance of the blue sub-pixel PB. In some designs, in order to present white light that satisfies human perception, the luminance contribution of green light is about 0.8 to 0.4, the luminance contribution of red light is about 0.4 to 0.2, and the luminance contribution of blue light is about 0.2 or less. Therefore, the green sub-pixel PG, the red sub-pixel PR, and the blue sub-pixel PB require different driving operations.

The driving transistors of the green sub-pixel PG, the red sub-pixel PR, and the blue sub-pixel PB may be designed to have different channel width to length ratios, so as to increase the flexibility of driving operation of individual sub-pixels. In some embodiments, the first driving transistor 112 of the green sub-pixel PG has a first channel width to length ratio of W₁/L₁, the second driving transistor 132 of the red sub-pixel PR has a second channel width to length ratio of W₂/L₂, and the third driving transistor 152 of the blue sub-pixel PB has a third channel width to length ratio of W₃/L₃. In some embodiments, 0.4≤W₁/L₁≤3, but not limited thereto. In some embodiments, 0.1≤W₂/L₂≤2, but not limited thereto. In some embodiments, 0.05≤W₃/L₃≤1, but not limited thereto. In some embodiments, the driving transistors of the green sub-pixel PG, the red sub-pixel PR, and the blue sub-pixel PB may be designed such that W₁/L₁>W₃/L₃, and W₂/L₂>W₃/L₃. In some embodiments, the driving transistors of the green sub-pixel PG, the red sub-pixel PR, and the blue sub-pixel PB may be further designed such that W₁/L₁>W₂/L₂, that is, W₁/L₁>W₂/L₂>W₃/L₃, but not limited thereto. When the driving transistors are designed to have different channel width to length ratios according to sub-pixels of different chromatic light, the driving operation of the green sub-pixel PG, the red sub-pixel PR, and the blue sub-pixel PB may be more flexible.

For example, in some embodiments, the light-emitting diodes adopted in the green sub-pixel PG, the red sub-pixel PR, and the blue sub-pixel PB have different luminous efficiencies. In order to achieve the required light emission luminance, it may be necessary to provide a larger driving current for the light-emitting diodes with poor luminous efficiency. However, under the configuration of driving transistors with different channel width to length ratios, it facilitates in allowing individual light-emitting diodes to achieve the desired luminance at an appropriate driving current. In some embodiments, the light-emitting diodes adopted in the green sub-pixel PG, red sub-pixel PR, and blue sub-pixel PB have different electrical characteristics. Under the same driving signal planning, it is not necessarily possible to provide the same luminous effects for all the light-emitting diodes, but it is necessary to provide corresponding driving signal planning for light-emitting diodes with different chromatic light. However, under the configuration of driving transistors with different channel width to length ratios, it facilitates in reducing the complexity of driving signals caused by the different electrical characteristics of the light-emitting diodes.

In some embodiments, the channel width of the first driving transistor 112 is W₁, the channel width of the second driving transistor 132 is W₂, and the channel width of the third driving transistor 152 is W₃. Meanwhile, the channel length of the first driving transistor 112 is L₁, the channel length of the second driving transistor 132 is L₂, and the channel length of the third driving transistor 152 is L₃. In some embodiments, W₁=W₂=W₃, and L₃>L₂>L₁. That is, the first driving transistor 112, the second driving transistor 132, and the third driving transistor 152 have the same channel width but different channel lengths. In some embodiments, L₃=L₂=L₁, and W₁>W₂>W₃. That is, the first driving transistor 112, the second driving transistor 132, and the third driving transistor 152 have the same channel length but different channel widths. In some embodiments, the first driving transistor 112, the second driving transistor 132, and the third driving transistor 152 may have different channel lengths and different channel widths. In addition, the driving transistor, the switching transistor, and the scanning transistor may be P-type thin film transistors or P-type metal-oxide-semiconductor field-effect transistors, but the disclosure is not limited thereto. In addition, in some embodiments, individual pixel driving circuits may also include other transistors, not limited to the 3T1C (3 transistors 1 capacitor) pixel circuit architecture shown in FIG. 1. For example, it may be a circuit architecture formed of seven transistors and two capacitors (7T2C), or may be a circuit architecture formed of eight transistors and two capacitors (8T2C), and the disclosure is not limited thereto.

Due to the variation in electron mobility among different semiconductor materials, selecting appropriate semiconductor materials for different thin film transistors may result in improved energy efficiency or display performance in display devices. In one embodiment, the semiconductor layer of the driving transistor may include low temperature polysilicon, and at least one of the switching transistor and the scanning transistor may include metal oxide. In another embodiment, the semiconductor layers of the driving transistor, the switching transistor, and the scanning transistor may all include low temperature polysilicon. In yet another embodiment, the semiconductor layers of the driving transistor, the switching transistor, and the scanning transistor may all include metal oxides. It may be known from the foregoing that the semiconductor layers of the driving transistor, the switching transistor, and the scanning transistor of the disclosure may use the same material or different materials. In addition, in one embodiment, the semiconductor material of the driving transistor of the blue sub-pixel is different from the semiconductor material of the driving transistor of the green sub-pixel and the red sub-pixel. For example, the semiconductor material of the driving transistor of the blue sub-pixel includes metal oxide, and the semiconductor material of the driving transistor of the green sub-pixel and the red sub-pixel includes low temperature polysilicon. In another embodiment, the semiconductor material of the driving transistor of the red sub-pixel is different from the semiconductor material of the driving transistor of the blue sub-pixel and the green sub-pixel. For example, the semiconductor material of the driving transistor of the red sub-pixel includes low temperature polysilicon, and the semiconductor material of the driving transistor of the blue sub-pixel and green sub-pixel includes metal oxide. However, the disclosure is not limited to the aforementioned embodiments.

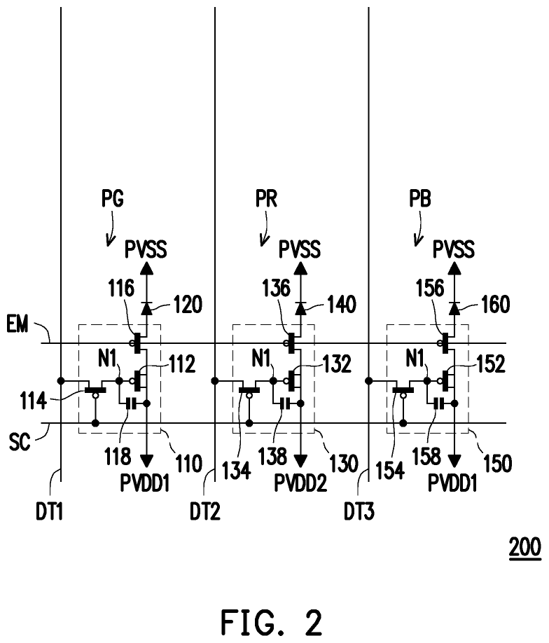

FIG. 2 is a schematic diagram of a display device according to an embodiment of the disclosure. A display device 200 includes a green sub-pixel PG, a red sub-pixel PR, and a blue sub-pixel PB. In FIG. 2, the green sub-pixel PG, the red sub-pixel PR, and the blue sub-pixel PB are substantially the same as the green sub-pixel PG, the red sub-pixel PR, and the blue sub-pixel PB in FIG. 1. Specifically, in this embodiment, the display device 200 provides the first operating voltage PVDD1 and the second operating voltage PVDD2 to drive the green sub-pixel PG, the red sub-pixel PR, and the blue sub-pixel PB. For example, the green sub-pixel PG and the blue sub-pixel PB are suitable for coupling with the first operating voltage PVDD1, and the red sub-pixel PR is suitable for coupling with the second operating voltage PVDD2, where PVDD2>PVDD1. In some embodiments, 6 volts≤PVDD2≤10 volts. In some embodiments, 5 volts≤PVDD1≤9 volts.

Referring to the embodiment in FIG. 1, the light-emitting element 120 of the green sub-pixel PG includes a green light-emitting diode, the light-emitting element 140 of the red sub-pixel PR includes a red light-emitting diode, and the light-emitting element 160 of the blue sub-pixel PB includes a blue light-emitting diode. The first terminal of the first driving transistor 112 is coupled to the first operating voltage PVDD1, the first terminal of the second driving transistor 132 is coupled to the second operating voltage PVDD2, and the first terminal of the third driving transistor 152 is coupled to the first operating voltage PVDD1. The red sub-pixel PR is coupled to the relatively large second operating voltage PVDD2, which facilitates in compensating the luminous efficiency of the red light-emitting diode, so that the green sub-pixel PG, the red sub-pixel PR, and the blue sub-pixel PB may readily achieve the desired luminous effects.

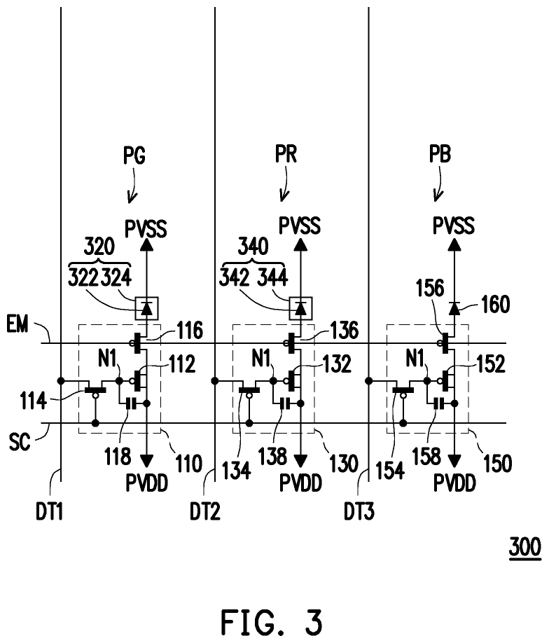

FIG. 3 is a schematic diagram of a display device according to an embodiment of the disclosure. A display device 300 includes a green sub-pixel PG, a red sub-pixel PR, and a blue sub-pixel PB. In FIG. 3, the green sub-pixel PG, the red sub-pixel PR, and the blue sub-pixel PB are substantially similar to the green sub-pixel PG, the red sub-pixel PR, and the blue sub-pixel PB in FIG. 1. Thus, the same reference numerals in both embodiments denote identical components or voltages, and details are not described herein. Specifically, the green sub-pixel PG in FIG. 3 may include a pixel driving circuit 110 and a light-emitting element 320. The pixel driving circuit 110 may refer to the description of FIG. 1, and the light-emitting element 320 may include a blue light-emitting diode 322 and a first light conversion element 324. The red sub-pixel PR in FIG. 3 may include a pixel driving circuit 130 and a light-emitting element 340. The pixel driving circuit 130 may refer to the description of FIG. 1, and the light-emitting element 340 may include a blue light-emitting diode 342 and a second light conversion element 344. The blue sub-pixel PB in FIG. 3 may include a pixel driving circuit 150 and a light-emitting element 160. Both the pixel driving circuit 150 and the light-emitting element 160 may refer to the description of FIG. 1. Since FIG. 3 mainly shows the components of individual sub-pixels in the form of circuit symbols, the first light conversion element 324 and the second light conversion element 344 are schematically shown in a block pattern, without limiting the specific structure of the light conversion elements. The first light conversion element 324 and the second light conversion element 344 may include quantum dots, fluorescent powders, phosphorescent powders, or color filters.

In this embodiment, the blue light-emitting diode 322 and the first light conversion element 324 are configured to realize green light, in which the first light conversion element 324 is suitable for being excited by the blue light-emitting diode 322 to emit yellow light or green light. Meanwhile, in this embodiment, the blue light-emitting diode 342 and the second light conversion element 344 are configured to realize red light, in which the second light conversion element 344 is suitable for being excited by the blue light-emitting diode 342 to emit red light. In addition, in this embodiment, a blue light-emitting diode is configured to realize blue light. Therefore, the green sub-pixel PG, the red sub-pixel PR, and the blue sub-pixel PB all adopt blue light-emitting diodes. In this embodiment, the first driving transistor 112, the second driving transistor 132, and the third driving transistor 152 have different channel width to length ratios, so that under the same driving signal, the effect of different luminance for different chromatic light may be achieved. This facilitates in increasing the flexibility of the driving operation of the green sub-pixel PG, the red sub-pixel PR, and the blue sub-pixel PB.

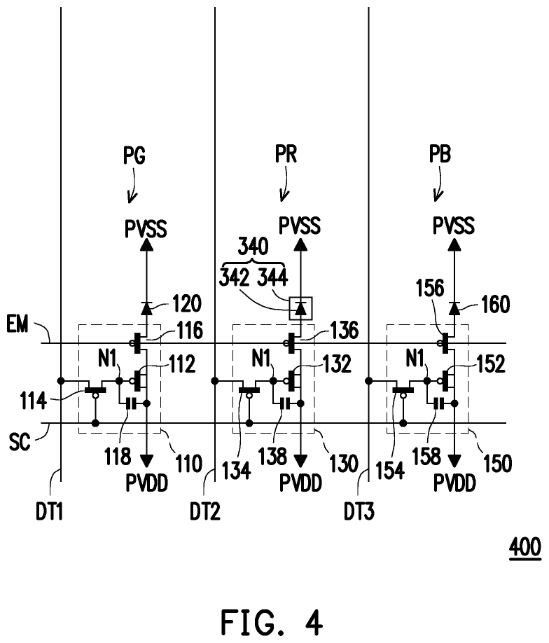

FIG. 4 is a schematic diagram of a display device according to an embodiment of the disclosure. A display device 400 includes a green sub-pixel PG, a red sub-pixel PR, and a blue sub-pixel PB. In FIG. 4, the green sub-pixel PG, the red sub-pixel PR, and the blue sub-pixel PB are substantially similar to the green sub-pixel PG, the red sub-pixel PR, and the blue sub-pixel PB in FIG. 1. Thus, the same reference numerals in both embodiments denote identical components or voltages, and details are not described herein. Specifically, the green sub-pixel PG in FIG. 4 may include a pixel driving circuit 110 and a light-emitting element 120. Both the pixel driving circuit 110 and the light-emitting element 120 may refer to the description of FIG. 1. The red sub-pixel PR in FIG. 4 may include a pixel driving circuit 130 and a light-emitting element 340. The pixel driving circuit 130 may refer to the description of FIG. 1, and the light-emitting element 340 may include a blue light-emitting diode 342 and a second light conversion element 344, as described in reference to FIG. 3. The blue sub-pixel PB in FIG. 4 may include a pixel driving circuit 150 and a light-emitting element 160. Both the pixel driving circuit 150 and the light-emitting element 160 may refer to the description of FIG. 1. Since FIG. 4 mainly shows the components of individual sub-pixels in the form of circuit symbols, the second light conversion element 344 is schematically shown in a block pattern, without limiting the specific structure of the light conversion element.

In this embodiment and the embodiment of FIG. 3, the red sub-pixel PR adopts the blue light-emitting diode 342 and the second light conversion element 344 to emit red light. The green sub-pixel PG, the red sub-pixel PR, and the blue sub-pixel PB may all be coupled to the same operating voltage PVDD, so as to exhibit similar luminous efficiencies. In addition, similar to the foregoing embodiments, the first driving transistor 112, the second driving transistor 132, and the third driving transistor 152 have different channel width to length ratios. In this way, the green sub-pixel PG, the red sub-pixel PR, and the blue sub-pixel PB of the display device 300, that is, the display device 400, have high flexibility in driving operation.

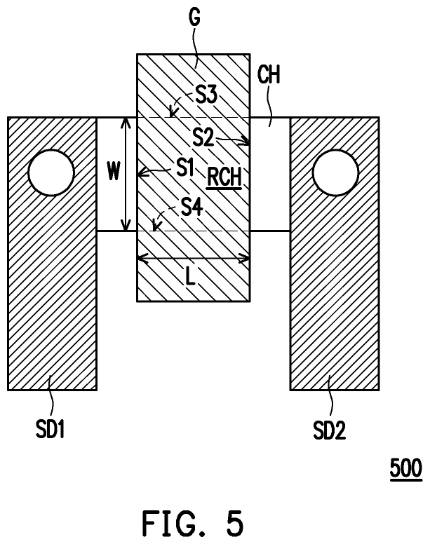

FIG. 5 is a schematic diagram of a driving transistor according to an embodiment of the disclosure. FIG. 5 schematically shows the main components of the driving transistor to illustrate the channel width and the channel length, but the actual structure of the driving transistor is not limited thereto. In FIG. 5, the driving transistor 500 includes a control terminal electrode G, a channel layer CH, a first terminal electrode SD1, and a second terminal electrode SD2. In some embodiments, the control terminal electrode G may be understood as a gate, one of the first terminal electrode SD1 and the second terminal electrode SD2 may be understood as a source, and the other one of the first terminal electrode SD1 and the second terminal electrode SD2 may be understood as a drain. The control terminal electrode G overlaps the channel layer CH, and is located between the first terminal electrode SD1 and the second terminal electrode SD2 in a top view. Meanwhile, the first terminal electrode SD1 and the second terminal electrode SD2 are connected to different parts of the channel layer CH. The overlapping configuration of the control terminal electrode G and the channel layer CH forms a channel region RCH, that is, a region where the control terminal electrode G and the channel layer CH overlap each other.

The channel region RCH has a first edge S1 adjacent to the first electrode SD1 and a second edge S2 adjacent to the second electrode SD2. The first edge S1 and the second edge S2 may be aligned with the contour edge of the control terminal electrode G. The channel region RCH also has a third edge S3 and a fourth edge S4 connected between the first edge S1 and the second edge S2. The third edge S3 and the fourth edge S4 are aligned with the contour edge of the channel layer CH, and the third edge S3 and the fourth edge S4 are opposite to each other.

In some embodiments, the first edge S1 and the second edge S2 may be parallel to each other, and the third edge S3 and the fourth edge S4 may be parallel to each other. In some embodiments, if the first edge S1, the second edge S2, the third edge S3, and the fourth edge S4 are all straight lines, then the channel length L of the driving transistor 500 refers to the distance between the first edge S1 and the second edge S2 of the channel region RCH, and the channel width W of the driving transistor 500 refers to the distance between the third edge S3 and the fourth edge S4 of the channel region RCH. In some embodiments, if the first edge S1, the second edge S2, the third edge S3, and the fourth edge S4 are not straight lines, then the channel width W of the driving transistor 500 may be equal to the length of the first edge S1 or the second edge S2, and the channel length L of the driving transistor 500 may be equal to the length of the third edge S3 or the fourth edge S4. Overall, the channel width W and channel length L of the driving transistor 500 may be measured along the contours of the control terminal electrode G and the channel layer CH under an optical microscope image. The structures, dimensions and measurements of the channel width W and channel length L described in FIG. 5 may be applied to the first driving transistor 112, the second driving transistor 132, and the third driving transistor 152 in FIG. 1 to FIG. 4.

To sum up, the display device of the disclosed embodiment adopts driving transistors with different channel width to length ratios, which facilitates in increasing the flexibility of driving control of individual sub-pixels. The disclosed embodiments may use driving transistors with different channel width to length ratios to drive sub-pixels of different colors according to the luminance requirements of different chromatic light. In some embodiments of the disclosure, light-emitting diodes with different light emission colors are matched with driving transistors with different channel width to length ratios, which may compensate for the differences in the characteristics of light-emitting diodes with different light emission colors, and reduce the complexity of driving control for sub-pixels of different colors.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. A display device, comprising:
a green sub-pixel, comprising a first driving transistor having a first channel width to length ratio being W₁/L₁;
a red sub-pixel, comprising a second driving transistor having a second channel width to length ratio being W₂/L₂; and
a blue sub-pixel, comprising a third driving transistor having a third channel width to length ratio being W₃/L₃, wherein W₁/L₁>W₃/L₃, and W₂/L₂>W₃/L₃.

2. The display device according to claim 1, wherein W₁/L₁>W₂/L₂.

3. The display device according to claim 1, wherein 0.4≤W₁/L₁≤3.

4. The display device according to claim 1, wherein 0.1≤W₂/L₂≤2.

5. The display device according to claim 1, wherein 0.05≤W₃/L₃≤1.

6. The display device according to claim 1, wherein the green sub-pixel and the blue sub-pixel are suitable for coupling with a first operating voltage, the red sub-pixel is suitable for coupling with a second operating voltage, the first operating voltage is PVDD1, the second operating voltage is PVDD2, and PVDD2>PVDD1.

7. The display device according to claim 6, wherein 6 volts≤PVDD2≤10 volts.

8. The display device according to claim 6, wherein 5 volts≤PVDD1≤9 volts.

9. The display device according to claim 1, wherein the first driving transistor, the second driving transistor, and the third driving transistor have a same channel width.

10. The display device according to claim 1, wherein the first driving transistor, the second driving transistor, and the third driving transistor have a same channel length.

11. The display device according to claim 1, wherein the blue sub-pixel comprises a blue light-emitting diode, the green sub-pixel comprises a blue light-emitting diode and a first light conversion element, and the red sub-pixel comprises a blue light-emitting diode and a second light conversion element.

12. The display device according to claim 1, wherein the blue sub-pixel comprises a blue light-emitting diode, the green sub-pixel comprises a green light-emitting diode, and the red sub-pixel comprises a red light-emitting diode.

13. The display device according to claim 1, wherein the green sub-pixel further comprises a first scanning transistor, a first switching transistor, and a first storage capacitor, a first terminal of the first storage capacitor is coupled to a first terminal of the first driving transistor, a second terminal of the first driving transistor is coupled to a first terminal of the first switching transistor, and a second terminal of the first storage capacitor is coupled to a control terminal of the first driving transistor.

14. The display device according to claim 13, wherein the first terminal of the first driving transistor is coupled to an operating voltage.

15. The display device according to claim 1, wherein the red sub-pixel further comprises a second scanning transistor, a second switching transistor, and a second storage capacitor, a first terminal of the second storage capacitor is coupled to a first terminal of the second driving transistor, a second terminal of the second driving transistor is coupled to a first terminal of the second switching transistor, and a second terminal of the second storage capacitor is coupled to a control terminal of the second driving transistor.

16. The display device according to claim 15, wherein the first terminal of the second driving transistor is coupled to an operating voltage.

17. The display device according to claim 1, wherein the green sub-pixel further comprises a third scanning transistor, a third switching transistor, and a third storage capacitor, a first terminal of the third storage capacitor is coupled to a first terminal of the third driving transistor, a second terminal of the third driving transistor is coupled to a first terminal of the third switching transistor, and a second terminal of the third storage capacitor is coupled to a control terminal of the third driving transistor.

18. The display device according to claim 17, wherein the first terminal of the third driving transistor is coupled to an operating voltage.

19. The display device according to claim 1, wherein a semiconductor material of the third driving transistor of the blue sub-pixel is different from a semiconductor material of the first driving transistor of the green sub-pixel and a semiconductor material of the second driving transistor of the red sub-pixel.

20. The display device according to claim 1, wherein a semiconductor material of the second driving transistor of the red sub-pixel is different from a semiconductor material of the third driving transistor of the blue sub-pixel and a semiconductor material of the first driving transistor of the green sub-pixel.
